(19) United States
(12) Patent Application Publication
(10) Pub. No.: US 2016/0079177 A1
(43) Pub. Date: Mar. 17, 2016

(54) WAFER AND METHOD FOR MANUFACTURING MICROSCOPIC STRUCTURE ON WAFER

(71) Applicant: Kabushiki Kaisha Toshiba, Minato-ku (JP)

(72) Inventor: Yusuke ARAYASHIKI, Yokkaichi (JP)

(73) Assignee: Kabushiki Kaisha Toshiba, Minato-ku (JP)

(21) Appl. No.: 14/612,456

(22) Filed: Feb. 3, 2015

Related U.S. Application Data
(60) Provisional application No. 62/049,181, filed on Sep. 11, 2014.

(51) Int. Cl. H01L 23/544; H01L 21/308; H01L 21/306; H01L 21/02

(52) U.S. Cl. CPC H01L 23/544; H01L 21/02282; H01L 21/3086; H01L 21/30604; H01L 2223/54426; H01L 2223/5446

(57) ABSTRACT

According to one embodiment, a method is disclosed for manufacturing a microscopic structure. The method can include forming a stacked body including a plurality of films on a substrate, an upper surface of a mark region of the substrate for alignment being formed at a position lower than an upper surface of a portion of the substrate where a structural pattern is to be formed, aligning the substrate and a template using a configuration of an upper surface of the stacked body formed in the mark region, coating a material in a liquid form or a semi-liquid form onto the stacked body, pressing the template onto the material; forming a pattern by curing the material, releasing the template from the pattern, and patterning the stacked body using the pattern as a mask.

### CROSS-REFERENCE TO RELATED APPLICATIONS

This application is based upon and claims the benefit of priority from U.S. Provisional Patent Application 62/049,181, filed on Sep. 11, 2014; the entire contents of which are incorporated herein by reference.

### FIELD

Embodiments described herein relate generally to a wafer and a method for manufacturing a microscopic structure on the wafer.

### BACKGROUND

In recent years, fine patterning of integrated circuits by nanoimprinting is being performed widely. In nanoimprinting, high precision of the alignment between the substrate and the template is necessary; and there are many cases where the alignment between the substrate and the template is performed by a method different from that of conventional photolithography. In nanoimprinting, precision alignment is performed by forming patterns (marks) for alignment in the substrate in which the pattern is formed and in the template mounted in the apparatus that forms the pattern, performing sensing from the apparatus side of moiré interference fringes occurring when the patterns are overlaid, and providing feedback to the relative positional information between the substrate and the template. However, there is a possibility that an irregular pattern may be formed in a process of patterning after the nanoimprinting, etc., according to the configuration of the mark for alignment formed on the substrate side, which may cause trouble in subsequent processes.

### BRIEF DESCRIPTION OF THE DRAWINGS

FIG. 1 is a plan view showing a mark region formed in a wafer, and a periphery of the mark region;

FIGS. 2A to 5C are cross-sectional views of processes, showing a method for manufacturing a microscopic structure according to an embodiment;

FIG. 6A is a cross-sectional view along line A-A′ shown in FIG. 1; and FIG. 6B is an enlarged view of portion B shown in FIG. 6A; and

FIG. 7A to FIG. 7C are cross-sectional views of processes, showing a method for manufacturing a microscopic structure according to a comparative example.

### DETAILED DESCRIPTION

In general, according to one embodiment, a method is disclosed for manufacturing a microscopic structure. The method can include forming a stacked body including a plurality of films on a substrate, an upper surface of a mark region of the substrate for alignment being formed at a position lower than an upper surface of a portion of the substrate where a structural pattern is to be formed, aligning the substrate and a template using a configuration of an upper surface of the stacked body formed in the mark region, coating a material in a liquid form or a semi-liquid form onto the stacked body, pressing the template onto the material; forming a pattern by curing the material, releasing the template from the pattern, and patterning the stacked body using the pattern as a mask.

Embodiments of the invention will now be described with reference to the drawings.

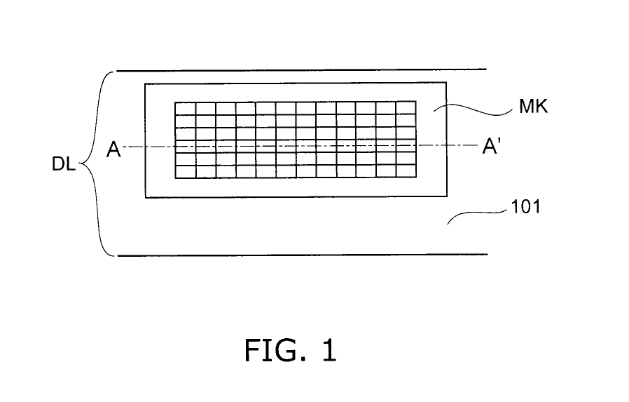

FIG. 1 is a plan view showing a mark region formed in a wafer, and the periphery of the mark region.

First, the configuration of the mark region will be described.

In the wafer according to the embodiment as shown in FIG. 1, a substrate 101 which is the unprocessed wafer is provided. A mark region MK which is a mark for alignment is formed in a portion on the substrate 101. The mark region MK has, for example, a quadrilateral configuration; and multiple quadrilateral regions are arranged in a matrix inside the frame of the quadrilateral. Specifically, regions where the upper surface is relatively high and regions where the upper surface is relatively low are arranged with each other along both the longitudinal direction and the lateral direction. The mark region MK is formed at a position lower than the major surface of the substrate 101. The mark region MK and the periphery of the mark region MK are set to be a dicing line DL. Generally, there are many cases where the alignment mark is formed on the dicing line DL. In other words, there are many cases where the mark region for alignment is formed in the scribe region in the singulation (singulation) of the wafer. However, the mark region for alignment may be formed in other locations.

A method for manufacturing the microscopic structure according to the embodiment will now be described.

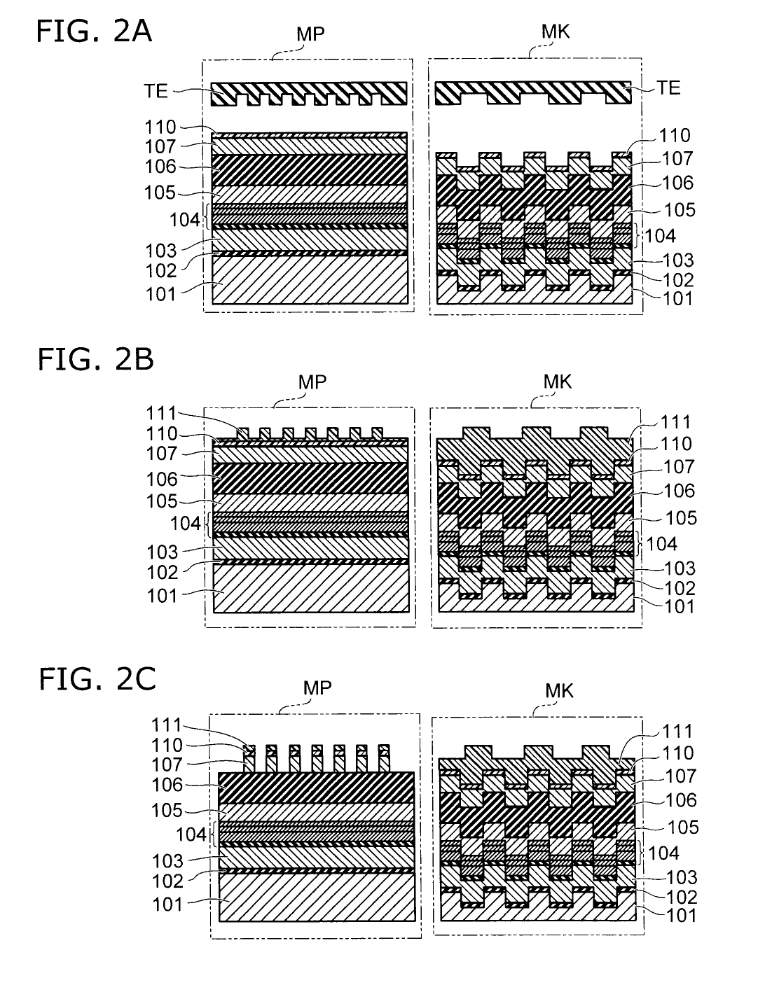

FIGS. 2A to 5C are cross-sectional views of processes, showing the method for manufacturing the microscopic structure according to the embodiment. In FIGS. 2A to 4B, the region where the main pattern is formed, i.e., the cross section of a main pattern region MP, is shown on the left side; and the cross section of the mark region MK is shown on the right side.

As shown in FIG. 2A, the upper surface of the substrate 101 is a plane in the main pattern region MP. On the other hand, in the mark region MK, a fine unevenness such as that described above is formed. The main pattern region MP is the portion where the circuit pattern of the microscopic structure is to be formed. The mark region MK is the portion where the alignment mark for alignment in the nanoimprinting is formed. Normally, although the mark region MK is formed on the dicing line DL, the mark region MK does not remain in the microscopic structure after the manufacturing because the mark region MK is removed in the dicing process of the manufacturing processes. The substrate may be a wafer. Also, the substrate may have a wafer and at least one of an insulative film and conductive film, provided on the wafer.

In the substrate 101, the maximum height of the upper surface of the mark region MK is lower than the upper surface of the main pattern region MP.

First, a barrier metal layer 102, a lower interconnect layer 103, a memory cell layer 104, a stopper film layer 105, hard mask layers 106 and 107, and an adhesion film layer 110 are stacked in this order from the lower layers on the substrate 101. At this time, in the mark region MK, the barrier metal layer 102, the lower interconnect layer 103, the memory cell layer 104, the stopper film layer 105, the hard mask layers 106 and 107, and the adhesion film layer 110 are stacked to inherit a fine uneven configuration formed in the upper surface of the substrate 101. The barrier metal layer 102 is formed using titanium, titanium nitride, tungsten nitride, etc. The lower interconnect layer 103 is formed using tungsten, etc. The films that are formed for the memory cell layer 104 are different according to how the microscopic structure stores information in the element structure. For example, in the case where a resistance random access memory element is used in which a metal oxide is used to store the information, a single stacked structure or multiple stacked structures that uses titanium oxide, hafnium oxide, tungsten oxide, etc., is used. Also, according to the characteristics of the memory element, there are cases where a diode made by using a stack of p-type and n-type silicon layers is introduced to the upper portion or lower portion of the memory cell region to provide a rectifying property to the circuit. Also, there are cases where a current-limiting layer having a high resistance is introduced to the upper portion or lower portion of the memory cell layer 104 to limit the current flowing in the circuit; and the layer of the current-limiting layer is formed using titanium silicon nitride, tantalum silicon nitride, etc. The stopper film layer 105 is a layer that functions as a stopper when performing planarization after the processes of patterning, processing and filling the inter-layer films and is formed of silicon nitride, tungsten, a tungsten compound, etc. The hard mask layers 106 and 107 are formed using one layer or multiple layers and are formed using amorphous silicon, a silicon oxide film, a silicon nitride film, etc. The formation in the example is of a stack of a silicon oxide film and amorphous silicon. The adhesion film layer 110 is a layer that functions as a layer that improves the adhesion between the substrate 101 and a resist material filled in the nanoimprinting and is formed of a material that uses a compound of silicon and carbon that is close to the resist material.

Each layer is stacked so that the thickness is substantially about the same between the main pattern region MP and the mark region MK. Therefore, the height of the upper surface of the adhesion film layer 110 in the mark region MK is lower than the height of the upper surface of the adhesion film layer 110 in the main pattern region.

Then, a template TE is disposed above the adhesion film layer 110. At this time, precision alignment of the template TE is performed by overlaying the fine unevenness formed in the adhesion film layer 110 of the mark region MK and the similar unevenness formed in the template TE, performing sensing from the apparatus side of the moiré interference fringes occurring due to the optical interference occurring between the two lattices, and providing feedback to the alignment information of the template.

Then, as shown in FIG. 2B, a resist in a liquid form or a semi-liquid form is filled between the adhesion film layer 110 and the template TE. At this time, because the mark region MK is lower than the main pattern region, the resist is filled sufficiently so that the amount for the height of the mark region MK can be filled. Then, the template TE is stamped toward the substrate 101 side. Continuing, after curing the resist by methods such as UV irradiation, heating, etc., a resist pattern 111 is formed on the adhesion film layer 110 by releasing the template. At this time, the thickness of the resist pattern 111 in the mark region MK is formed to be thicker than the thickness of the resist pattern 111 in the main pattern region MP.

Then, as shown in FIG. 2C, RIE (Reactive Ion Etching) patterning is performed using the resist pattern 111 as a mask. The RIE patterning is implemented at conditions so that selectivity is provided between the resist pattern 111 that includes carbon and the amorphous silicon layer included in the hard mask layer 107. Thereby, in the main pattern region MP, the adhesion film layer 110 and the hard mask layer 107 using amorphous silicon are selectively removed; and the adhesion film layer 110 and the hard mask layer 107 are patterned. On the other hand, in the mark region MK, the patterning stops only at the resist pattern 111 because the resist pattern 111 is thick; and the hard mask layer 107 is not patterned.

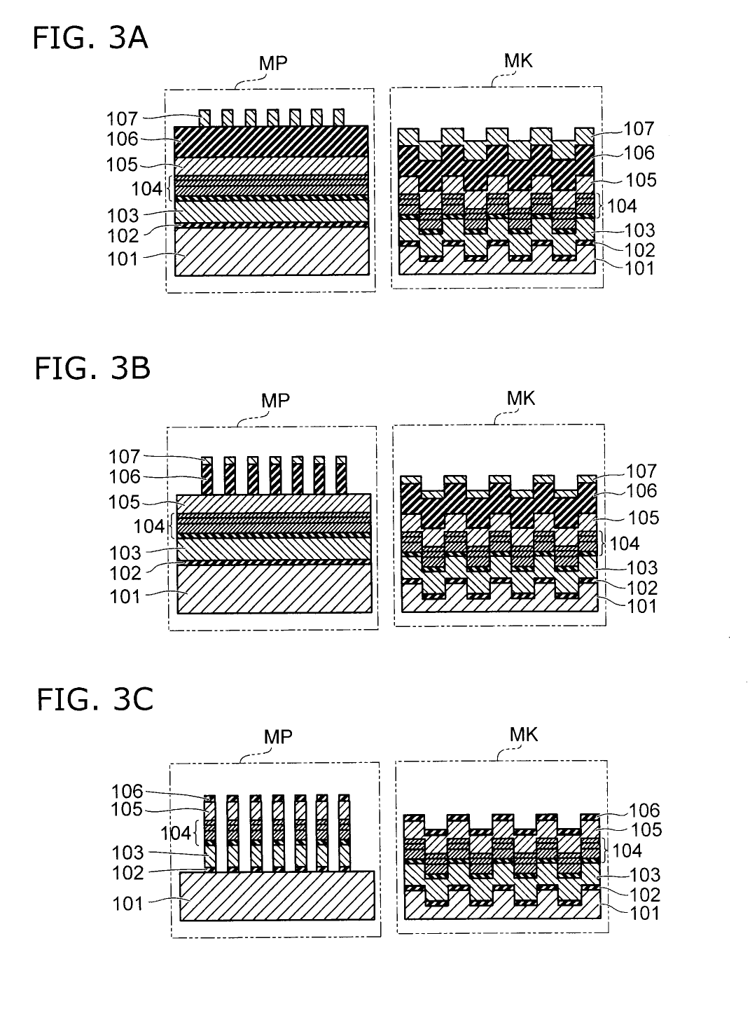

Continuing as shown in FIG. 3A, the adhesion film layer 110 and the resist pattern 111 using the carbon-based film are removed by oxygen ashing. At this time, the hard mask layer 107 using the already-patterned amorphous silicon remains in the main pattern region MP. On the other hand, in the mark region MK, the hard mask layer 107 is not patterned because the patterning stopped at the resist pattern 111; and the films at and below the amorphous silicon remain in layered configurations. Here, although the oxygen ashing is described as being performed after the patterning of the amorphous silicon layer, as long as sufficient selectivity with the resist is provided, the oxygen ashing may be performed after performing up to the patterning of the silicon oxide film layer.

Then, as shown in FIG. 3B, RIE is performed using the hard mask layer 107 as a mask. Thereby, the hard mask layer 106 is patterned in the main pattern region MP. On the other hand, the hard mask layer 106 is not patterned in the mark region MK where the hard mask layer 107 is not patterned.

Then, as shown in FIG. 3C, in the main pattern region MP, the stopper film layer 105, the memory cell layer 104, the lower interconnect layer 103, and the barrier metal layer 102 are patterned by performing RIE using the hard mask layer 107 (referring to FIG. 3B) and the hard mask layer 106 as a mask. On the other hand, in the mark region MK, the films of the layers under the hard mask layer 106 are not patterned because the hard mask layer 107 is not patterned.

At this time, although the stacked structure of the mark region MK ideally should be the same as the remaining film structure patterned in the main pattern region MP, there is a possibility of being patterned deeper due to fluctuation of the etching rate due to coverage differences of the patterns. However, even in such a case, there is no risk of pattern breakage, etc., in the subsequent processes because the films that are not patterned remain in layered configurations.

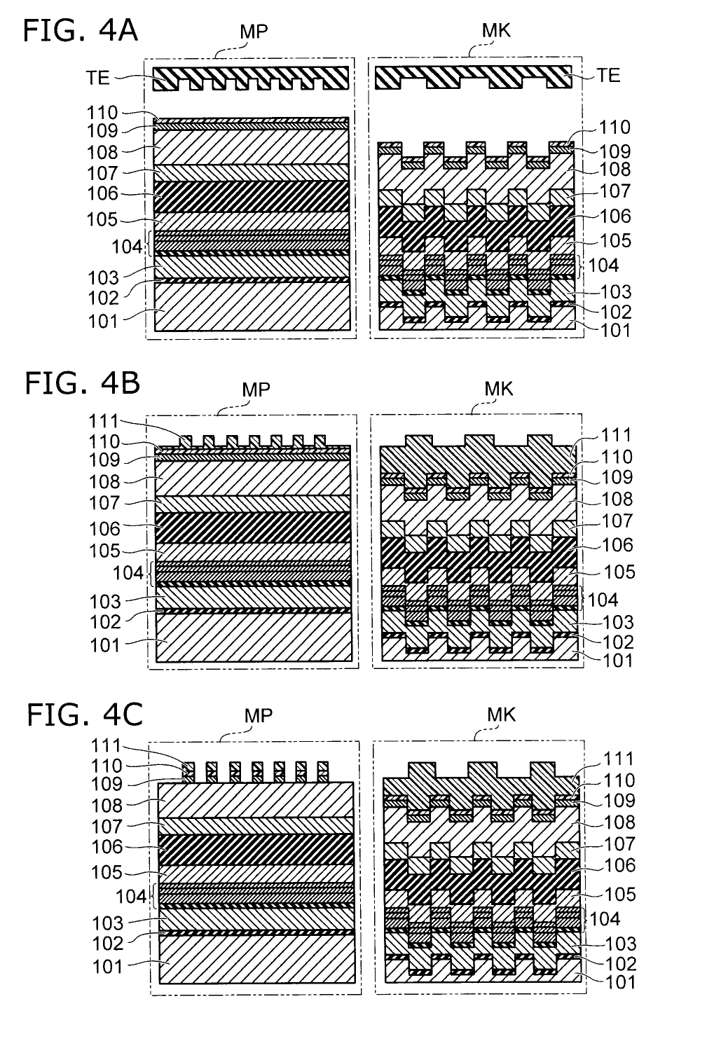

An example will now be described in the case where a transfer process is used instead of the patterning using only the resist. Generally, in the case where fine patterning is implemented, collapse, rounding, etc., of the pattern undesirably occurs and discrepancies occur in the pattern configuration when the resist height of the fine pattern becomes too high. Also, particularly in the case of a nanoimprint process, there is a possibility that discrepancies such as unfilled resist between the substrate 101 and the template, defects when releasing the template, etc., may occur; and the height of the resist that can be patterned naturally is limited. On the other hand, in the case where it is necessary for the height of the resist used as the mask for patterning the films of the lower layers to be not less than a constant height, but the resist height is insufficient for the patterning, it is desirable for a CT layer 108 and a SOG layer 109 to be formed in layers under the resist pattern 111 as layers that transfer the resist pattern 111. The stacked structure in such a case is shown in FIG. 4A to FIG. 4C.

As shown in FIG. 4A, similarly to the description described above, the adhesion film layer 110 is formed after forming up to the hard mask layers 106 and 107 and then forming the CT layer 108 and the SOG layer 109.

Then, as shown in FIG. 4B, the resist pattern 111 is formed by nanoimprinting.

Then, as shown in FIG. 4C, the adhesion film layer 110 and the SOG layer 109 are patterned using the resist pattern 111 as a mask. At this time, the patterning stops at the resist because the film thickness of the resist is formed to be thick in the mark region MK.

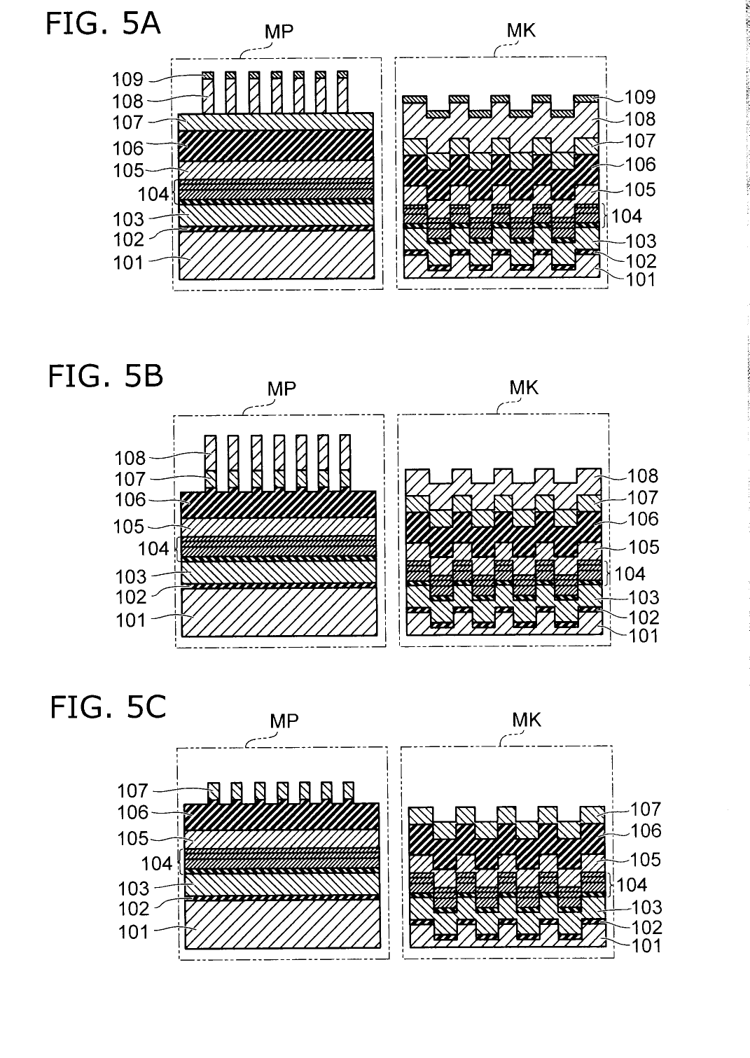

Then, as shown in FIG. 5A, the CT layer 108 is patterned using the residual film of the resist pattern 111 and the SOG layer 109 as a mask.

Then, as shown in FIG. 5B, the hard mask layer 107 which is the amorphous silicon layer is patterned using the CT layer 108 as a mask. At the stage at which the CT layer 108 is patterned, in the mark region MK, the patterning stops at the SOG layer 109 or stops at the stage in which the CT is patterned somewhat. The patterning stops at the CT layer 108 in the mark region MK because sufficient selectivity can be provided with the CT in the following patterning of the hard mask layer 106.

Then, as shown in FIG. 5C, the CT layer 108 is removed by implementing oxygen ashing. The processes shown in FIGS. 3B and 3C are implemented for the layers thereinafter similarly to the case where the CT and the SOG layer 109 described above do not exist.

Thus, the microscopic structure according to the embodiment is manufactured.

A wafer manufactured using the method for manufacturing the microscopic structure according to the embodiment will now be described.

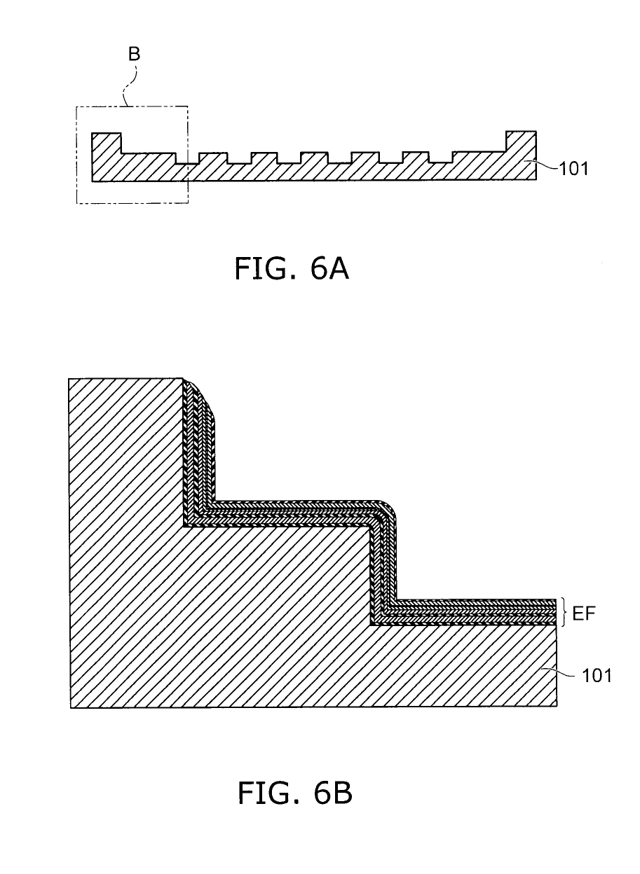

FIG. 6A is a cross-sectional view along line A-A′ shown in FIG. 1; and FIG. 6B is an enlarged view of portion B shown in FIG. 6A.

As shown in FIG. 6A, the mark region MK has a recessed configuration made in the upper layer portion of the substrate 101; and a fine unevenness is formed in the bottom surface of the recess.

As shown in FIG. 6B, an etching film EF remains on the side wall portion of the recess and the side wall portion of the fine unevenness of the mark region MK. The etching film EF includes, for example, the materials used in the processes of forming the microscopic structure such as the mask materials, the insulating films, the conductive films, etc. In the wafer manufactured using the method for manufacturing the microscopic structure according to the embodiment, the etching film EF is formed at a position that is lower than the major surface of the substrate 101.

Effects of the embodiment will now be described.

In the embodiment, the alignment pattern is lower than the main pattern region MP by providing the mark region MK for alignment used in the imprint method at a position that is lower than the major surface of the substrate 101. Thereby, the lithography pattern is not transferred in the mark region MK for the patterning after the stamping by the template TE. Thereby, in the mark region MK, trouble such as pattern breakage when aligning, etc., can be prevented because the films provided on the substrate 101 are not patterned into irregular configurations.

A method for manufacturing a microscopic structure according to a comparative example will now be described.

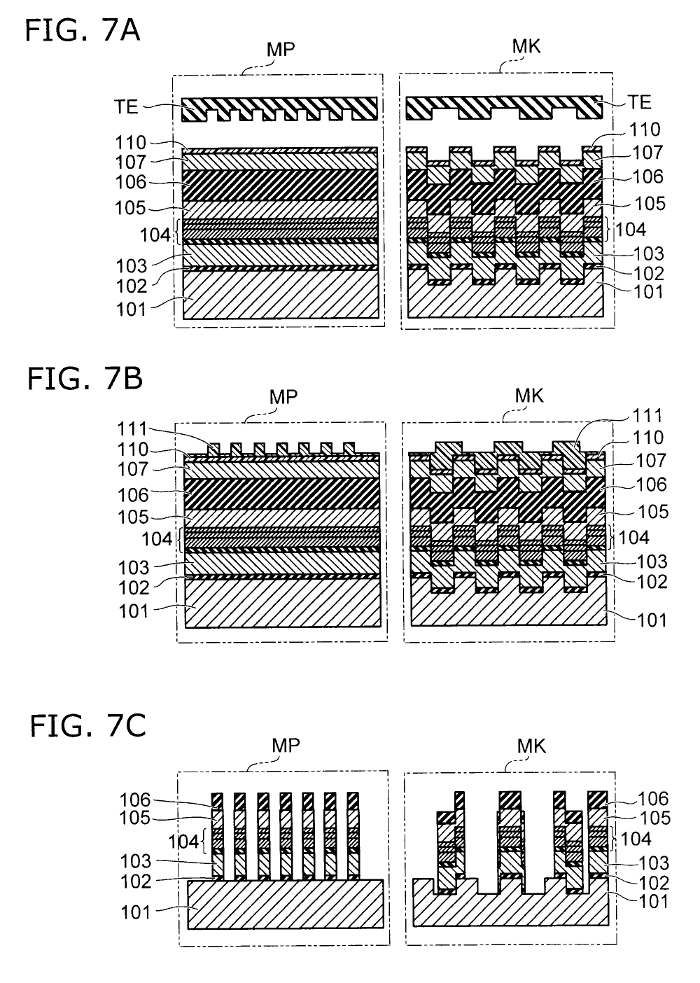

FIG. 7A to FIG. 7C are cross-sectional views of processes, showing the method for manufacturing the microscopic structure according to the comparative example. In FIG. 7A to FIG. 7C, the region where the main pattern is formed, i.e., the cross section of the main pattern region MP, is shown on the left side; and the cross section of the mark region MK is shown on the right side.

In the comparative example, as shown in FIG. 7A, the major surface of the substrate 101 of the main pattern region MP and the maximum height of the mark region MK are at the same height.

First, the barrier metal layer 102, the lower interconnect layer 103, the memory cell layer 104, the stopper film layer 105, the hard mask layers 106 and 107, the CT layer 108, the SOG layer 109, and the adhesion film layer 110 are stacked in this order from the lower layers on the substrate 101. At this time, in the mark region MK, the barrier metal layer 102, the lower interconnect layer 103, the memory cell layer 104, the stopper film layer 105, the hard mask layer 106 and 107, the CT layer 108, the SOG layer 109, and the adhesion film layer 110 are stacked to inherit the fine uneven configuration formed in the upper surface of the substrate 101.

Then, the template TE is fixed above the adhesion film layer 110. At this time, the alignment of the template TE is performed by an imprint method utilizing the fine unevenness formed in the adhesion film layer 110 of the mark region MK.

Then, as shown in FIG. 7B, a resist is coated in a liquid form or a semi-liquid form onto the adhesion film layer 110.

Subsequently, the resist pattern 111 is formed on the adhesion film by stamping onto the resist, curing the resist by a method such as UV irradiation, heating, etc., and by releasing the template. At this time, recesses and protrusions do not always match between the substrate 101 side and the template side because both the size and period are different between the unevenness pattern having the lattice configuration formed on the substrate 101 and the unevenness pattern formed on the template side, and because shifting in the XY-direction occurs according to the degree of the alignment.

Then, as shown in FIG. 7C, the desired pattern is formed by sequentially patterning the films of the lower layers using the resist pattern 111 as a mask by RIE. At this time, as described above, an irregular pattern that cannot be controlled appears in the mark region MK because the unevenness of the mark region on the template side and the unevenness of the mark region on the substrate 101 side do not overlap, and because the amount of the correction of the alignment is different between products. There is a possibility that pattern breakage may occur for such an irregular pattern and cause trouble in the subsequent processes such as patterning, cleaning processes, etc.

According to the embodiments described above, a method for manufacturing a microscopic structure having few occurrences of trouble such as pattern breakage when aligning, etc., can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a microscopic structure, comprising:
forming a stacked body including a plurality of films on a substrate, an upper surface of a mark region of the substrate for alignment being formed at a position lower than an upper surface of a portion of the substrate where a structural pattern is to be formed;
aligning the substrate and a template using a configuration of an upper surface of the stacked body formed in the mark region;
coating a material in a liquid form or a semi-liquid form onto the stacked body;
pressing the template onto the material;
forming a pattern by curing the material;
releasing the template from the pattern; and
patterning the stacked body using the pattern as a mask.

2. The method for manufacturing the microscopic structure according to claim 1, wherein
the patterning of the stacked body includes performing anisotropic etching using the pattern as a mask, and
at least one film of an upper layer portion of the stacked body is selectively removed based on the pattern in the performing of the anisotropic etching at the portion where the circuit pattern is to be formed.

3. A method for manufacturing a microscopic structure, comprising:
aligning a template and a substrate, an upper surface of a mark region of the substrate for alignment being formed at a position lower than an upper surface of a portion of the substrate where a structural pattern is to be formed;
coating a material in a liquid form or a semi-liquid form onto the substrate;
contacting the template and the material each other;
forming a pattern by curing the material;
separating the template and the pattern; and
processing the substrate using the pattern as a mask.

4. The method for manufacturing the microscopic structure according to claim 3, wherein
The processing the substrate includes performing anisotropic etching using the pattern as a mask to remove substrate selectively.

5. A wafer, comprising:
a pattern formation region where a structural pattern is to be formed, the pattern formation region being a portion of one surface; and
a mark region where a mark for alignment to be used in imprinting is formed, the mark region being one other portion of the one surface,
an upper surface of the mark region being formed at a position lower than an upper surface of the pattern formation region.

6. The wafer according to claim 5, wherein
an unevenness is formed in the mark region, and
an etching film is formed on at least one of a side surface of the unevenness or a side surface of a stepped portion formed at a boundary between the mark region and a portion where the structural pattern is to be formed.

7. The wafer according to claim 5, wherein the mark region is disposed inside a scribe region when singulating the wafer.
